(19) United States
(12) Patent Application Publication
(10) Pub. No.: US 2003/0154908 A1
(43) Pub. Date: Aug. 21, 2003

(54) Manufacturing method and apparatus

(76) Inventors: Dominic George Webber, Cambridge (GB); Richard John Topliss, Cambridge (GB)

Correspondence Address: FINNEGAN, HENDERSON, FARABOW, GARRETT & DUNNER, LLP, 1300 I STREET, NW, WASHINGTON, DC, 20005, US

(21) Appl. No.: 10/129,368

(22) PCT Filed: Nov. 3, 2001
(86) PCT No.: PCT/GB00/04260

(51) Int. Cl. C30B 13/00; C30B 21/04; C30B 28/08

(52) U.S. Cl. 117/44

(57) ABSTRACT

An etching system (1) comprises a host PC (20) which stores a bitmap etching pattern (210) and transmits this via its own interface (200) and a data link (30) to an etching apparatus (10). The etching apparatus (10) includes its own interface (170) which receives the bitmap etching pattern (210) and passes it onto a control unit (110). The control unit (110) generates control signals for an etching head driver (120) which in turn drives an etching head (130) to eject etchant from an etching reservoir onto an item to be etched. The etching head (130) is moved relative to the item to he etched by means of motors (151, 152) which are driven by motor drivers (141, 142) which are also controlled by the control unit (110). The etching head (130) selectively deposits droplets of etchant onto the item to be etched in such a way that unwanted portions are removed by the droplets of etchant whilst wanted portions are maintained intact.

The present invention relates to a manufacturing method and apparatus, and in particular to a manufacturing method involving, and an apparatus for, etching of a metallic layer or a metallic billet.

Many different destructive manufacturing processes are known in which unwanted material is selectively removed. An example of a destructive manufacturing method is photochemical machining which is used for example in the manufacture of small (typically of the order of a few square centimetres, but possibly right up to a square metre or more), thin (of the order of a few hundreds of microns to a few millimetres) metallic parts having a fairly complex two dimensional shape. Such parts find applications in, for example, mobile telephones. The photochemical machining method conventionally employed for manufacturing such parts involves producing a photomask (sometimes referred to as a photo-tool) which is a negative of the final shape of the desired part; applying a photosettable resist to a thin slab of metal from which the desired part is to be formed; exposing the photosettable resist to ultraviolet light through the photomask (this is preferably done on both sides of the starting piece of metal); rinsing away the unset resist to expose the unwanted metal; and passing the piece thus formed through an etching chamber in which the exposed metal is etched away by means of a suitable chemical etchant.

A number of metal-etchants are well known. A large number of metal etchants are, for example, based on ferric chloride with varying amounts of additives etc. for particular metals. In general, such metal etchants will not affect non-metallic materials, especially glass or other ceramics, or plastics materials. Such materials will hereinafter be referred to as metal-etchant resistant materials even though there may clearly be some corrosive compounds which could be used to etch both say a metal and a ceramic, such compounds are not typically used to perform metallic etching because a more metal specific etchant is more preferably used.

There are a number of drawbacks associated with photochemical machining. One drawback is that the process actually involves two rather distinct sub-processes, the first being to make the photomask and the second being to perform the photoresist patterning and the etching. These two sub-processes are normally carried out in separate places by separate people and delays can result from coordinating these two separate sub-processes. Furthermore, the second sub-process actually requires a large number of distinct manufacturing steps. For example, the second sub-process may typically involve preparing the metal piece to be etched by degreasing, acid washing, scrubbing and drying its surfaces so that the photoresist will bond to it; laminating the photoresist onto the surfaces of the metal piece, placing the photomasks onto the surfaces; exposing the masked piece to ultraviolet light; developing the image by dissolving unexposed photoresist; placing the metal piece into an etching chamber and performing etching; stripping of the remaining photomist with an alkaline wash; and then performing a final inspection to ensure that no further processing is required. Each of these steps takes time and queues can form for each stage which slows down the overall process.

A further drawback with this method concerns the etching chamber. Different etchants are typically required for optimum etching of different metals. However, in a conventional etching chamber it is not possible to readily switch between different types of etchant and thus it is difficult to machine different types of metal. Therefore, in practice the machining of unusual materials is queued until a sufficiently large batch is generated to make it worthwhile changing to the required etchant. This can cause delays in the machining of unusual materials, especially for prototyping purposes where only a small number (e.g. one) of machine parts are required.

Another application of photochemical machining is in applying fine-detail surface structure to mould tools which are then used to form injection-moulded pieces having a desired textured surface (e.g. to imitate the surface appearance of natural leather). In such a case, the overall shape of the mould tool is formed using an alternative method such as electro-discharge machining (which is described in more detail below) and then photomasks having the correct surface patterns are adhered to the irregular shape of the mould tool before performing photochemical machining as described above. This process is awkward, time consuming and prone to the formation of errors or deformations in the final surface pattern produced.

Another conventional destructive manufacturing method is electro-discharge machining (EDM). Conventional EDM is typically used for producing mould tools for use in manufacturing injection moulded parts for use in, for example, electronic consumer products. EDM involves firstly manufacturing a number of appropriately shaped electrodes of increasing detail out of a soft material such as carbon. This can be done using conventional milling apparatus. A large potential difference is then set up between the first electrode, having the desired general shape but no detail, and a billet of metal to be machined and the electrode is driven into the billet. Whenever a point on the surface of the electrode approaches the surface of the billet, a spark is generated between the electrode and the billet which destroys the small portion of the billet which is energised by the spark. The process is then repeated with the successive electrodes generating successive levels of detail until the last electrode is driven in which causes the very smallest details in the mould tool to be formed. This method has the drawback that again two separate sub-processes are required, namely the first sub-process of manufacturing the electrodes and then the second sub-process of using the electrodes to machine the billet of metal. These processes are typically performed separately and thus co-ordinating delays can occur. Secondly, each of these processes is fairly expensive (requiring expensive machinery) and lengthy each subprocess again requires a number of steps.

According to one aspect, the present invention seeks to provide on alternative destructive manufacturing method and apparatus.

According to a first aspect of the present invention, there is provided a method of manufacturing an item having a desired shape from a starting piece of material having a different shape, said method comprising the step of selectively depositing etchant onto unwanted portions of the initial piece of material.

This method avoids the need to firstly produce either a photomask (sometimes referred to as a photo-tool) as required by photochemical machining, or electrodes as is required in EDM. Furthermore, nearly all of the steps of the second sub-process of photochemical machining are avoided or simplified (e.g. no etching chamber is required, and, although some metal surface preparation is required, this is less stringent than that required for preparing a surface to receive photoresist.

According to a second aspect of the present invention, there is provided apparatus for manufacturing an item having a desired shape from an initial piece of material, said apparatus comprising an etching head for selectively depositing etchant onto said initial piece of material and preferably includes movement means for providing relative movement between the etchant head and the initial piece of material; whereby the etchant head may selectively deposit etchant on unwanted parts of the initial piece of material in order to manufacture the item having the desired shape.

Such apparatus again avoids the need to perform a large number of the steps associated with photochemical machining or EDM.

In order that the invention may be better understood, embodiments thereof will now be described, by way of example only, with reference to the accompanying drawings in which:

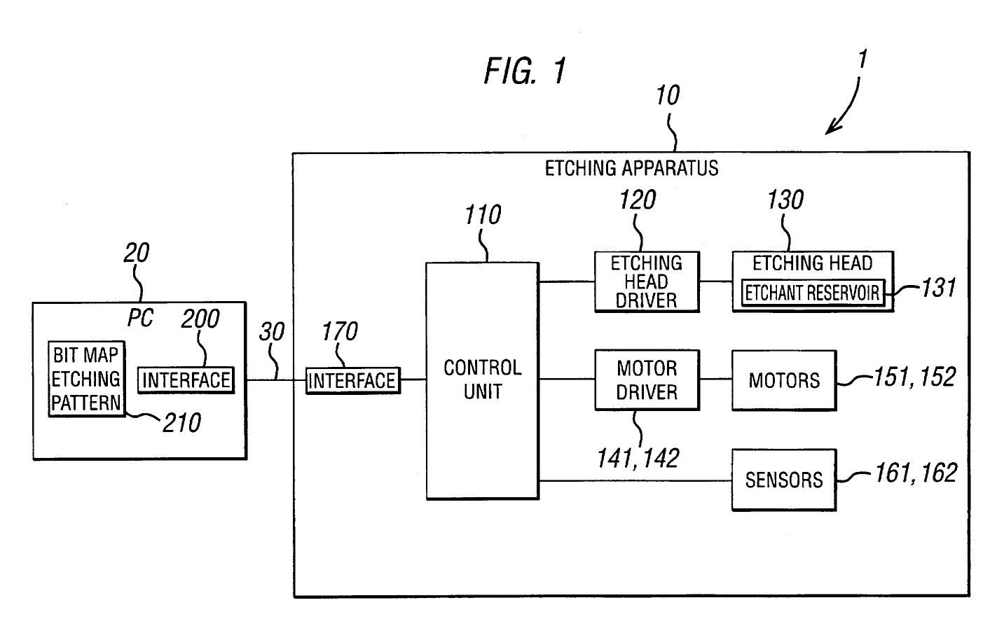

FIG. 1 is a block diagram of an etching system according to a first embodiment of the present invention;

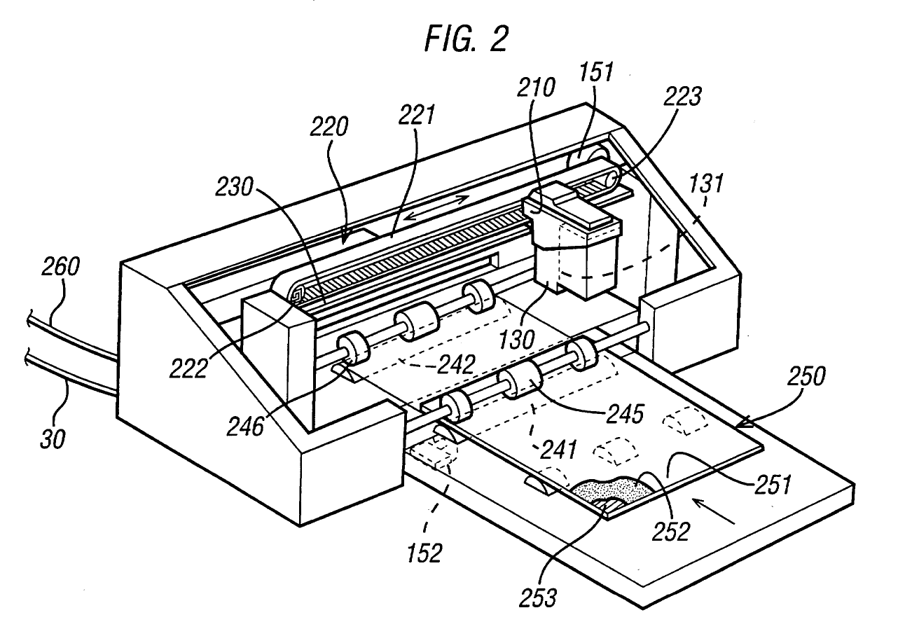

FIG. 2 is a diagrammatical perspective view of etching apparatus forming part of the etching system of FIG. 1;

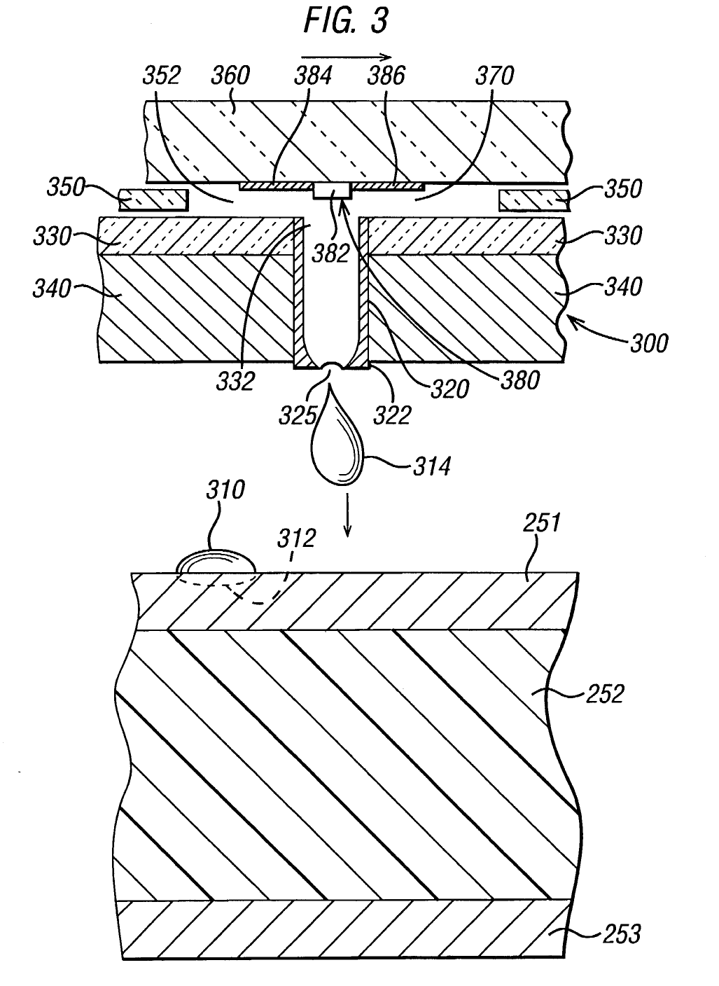

FIG. 3 is an enlarged diagrammatical cross-sectional view through an etching head and an item to be etched shown in FIG. 2;

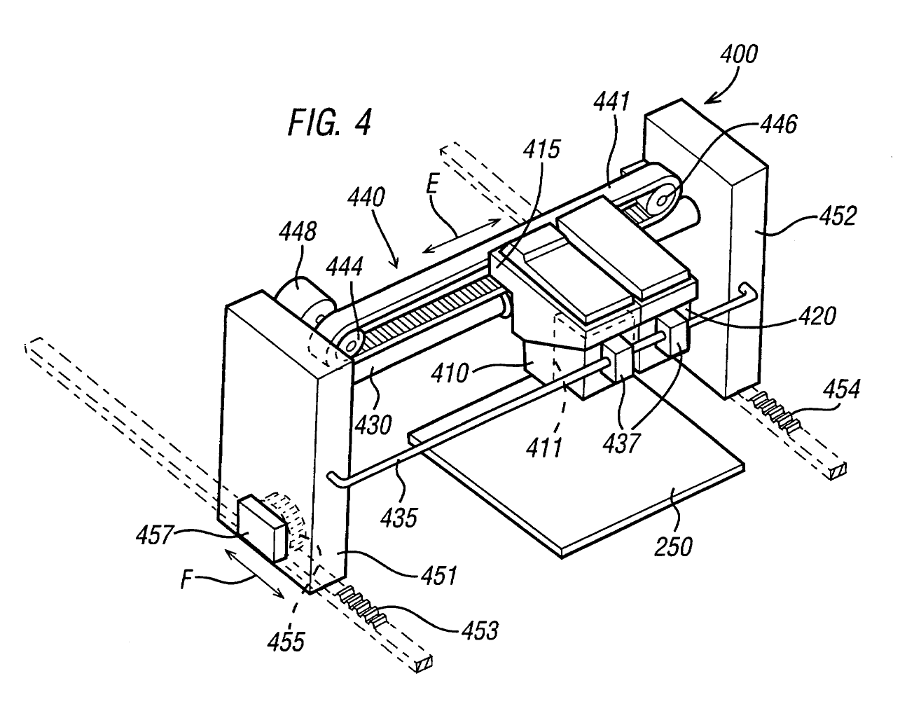

FIG. 4 is a diagrammatical perspective view of the mechanical arrangement of an etching apparatus according to a second embodiment of the present invention;

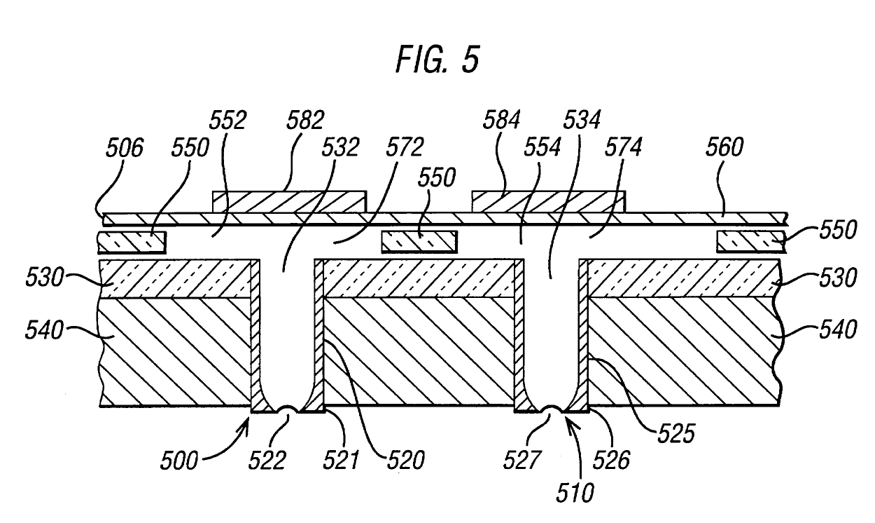

FIG. 5 is an enlarged cross-sectional view of the etching head shown in FIG. 4;

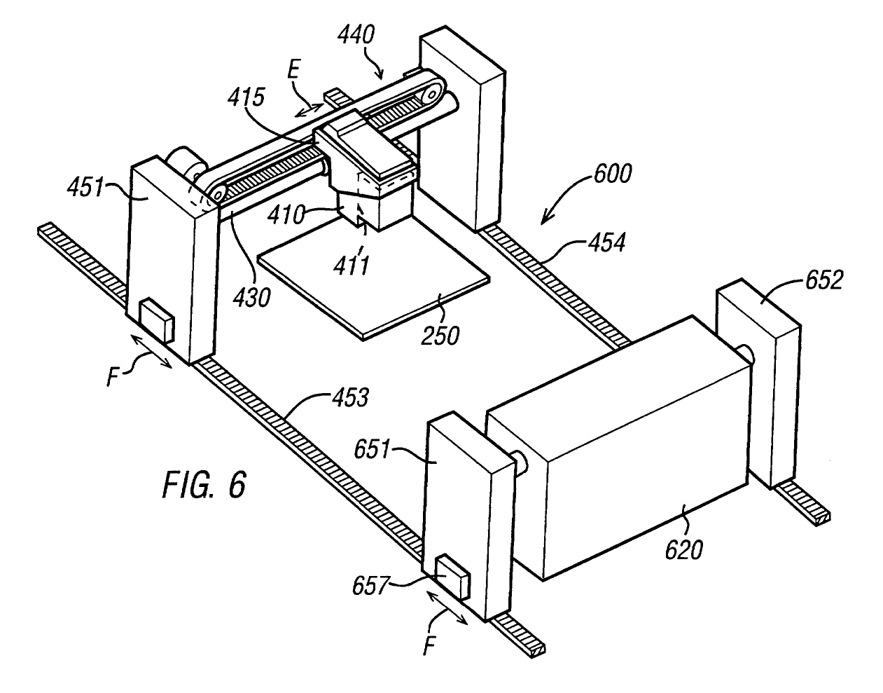

FIG. 6 is a diagrammatical perspective view of the mechanical arrangement of an etching apparatus according to a third embodiment of the present invention;

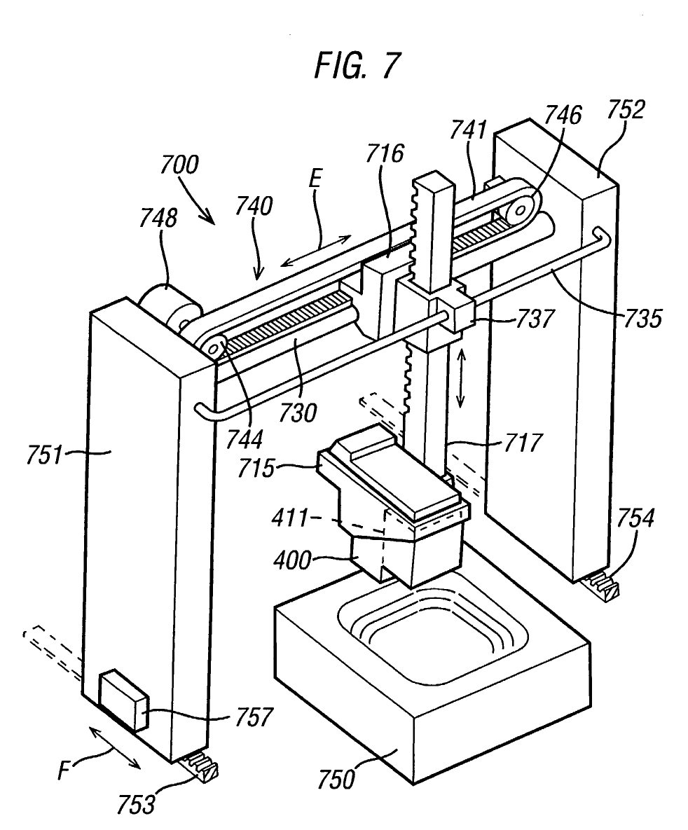

FIG. 7 is a diagrammatical perspective view of the mechanical arrangement of an etching apparatus according to a fourth embodiment of the present invention;

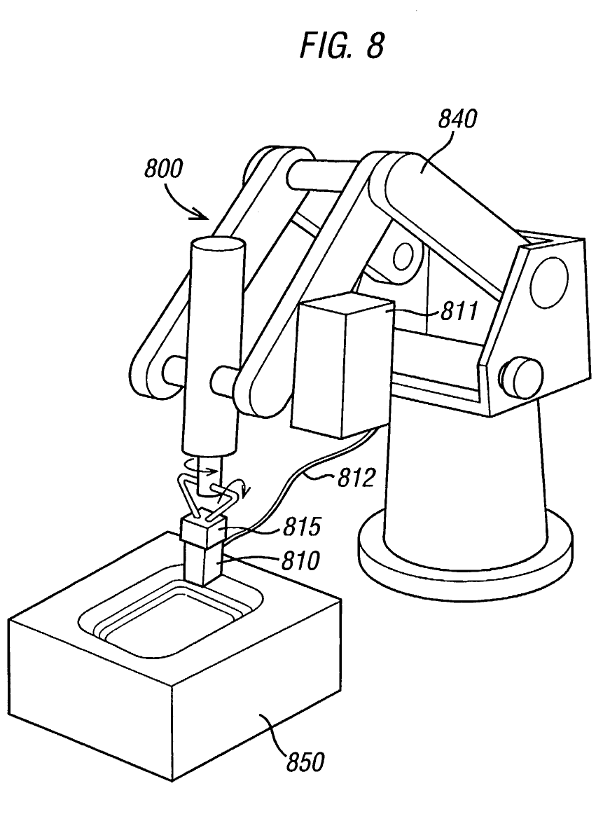

FIG. 8 is a diagrammatical perspective view of the mechanical arrangement of an etching apparatus according to a fifth embodiment of the present invention; and

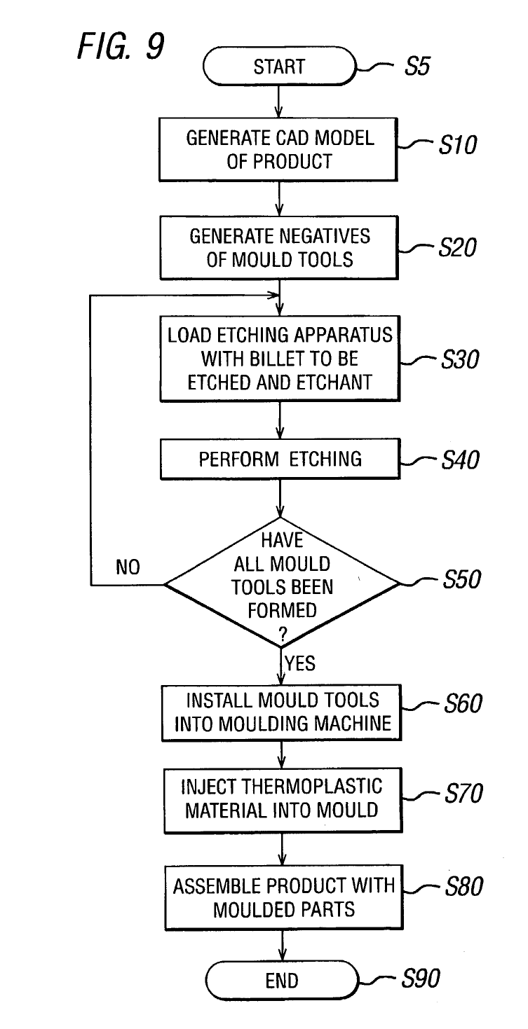

FIG. 9 is a flow diagram illustrating the manufacturing steps involved in manufacturing a consumer product including moulded parts formed from plastics material in accordance with the present invention.

Embodiment 1

FIG. 1, shows an etching system 1 for selectively etching unwanted portions of an initial working piece, which in this embodiment is a nineteen micron thick layer of copper forming the upper layer of a printed circuit board. As shown, the etching system 1 comprises a personal computer 20, etching apparatus 10 and a data link 30 connecting personal computer 20 to the etching apparatus 10. The personal computer 20 enables a user to generate an etching pattern and also controls the operation of the etching apparatus 10. The personal computer 20 transmits a bitmap 210 of the etching pattern generated by a user via an interface 200 onto the data link 30 which connects to the etching apparatus 10.

Within the etching apparatus 10, a similar interface 170 receives the bitmap etching pattern 210 from the data link 30 and passes this onto control unit 110. The control unit 110 generates control signals for controlling motor drivers 141, 142. The motor drivers 142 in turn generate control signals for driving a first motor 151 for moving an etching head 130 in a scanning direction and the second motor 152 for moving the printed circuit board to be etched in a sub-scanning direction. The control unit 110 also generates control signals for controlling an etching head driver 120. The etching head driver 120 in turn generates voltage pulses which cause the etching head 130 to selectively eject droplets of etchant onto the printed circuit board to be etched at appropriate times in accordance with the bitmap etching pattern 210 transmitted by the personal computer 20. The etchant is stored within an etchant reservoir 131 which forms part of the etching head 130. The etching apparatus in turn also includes a first sensor 161 for providing feedback information to the control unit 110 about the position of the etching apparatus 130, and a second sensor 162 for providing feedback information to the control unit 110 about the position of the printed circuit board in the sub-scanning direction.

FIG. 2 is a diagrammatical illustration of the etching apparatus 10 illustrating in particular the arrangement of the mechanical parts of the etching apparatus 10. Also, shown in FIG. 2 is a printed circuit board (PCB) 250 having a first copper layer 251 of approximately 19 microns thickness, a substrate 252 made of plastics material and having a thickness of approximately 300 microns and a second copper layer 253 again having a thickness of approximately 19 microns. The printed circuit board 250 will hereinafter be referred to as the item to be etched or simply as PCB 250.

The etching head 130, which includes the etchant reservoir 131 is removably mounted within a carriage 210, which in turn, is mounted on a scanning guide rail 230. The carriage 210 is driven by a drive belt mechanism 220 which includes a scanning drive belt 221, first and second pullies 222, 223 around which the drive belt 221 is supported and the first motor 151 (which is driven by the first motor driver 141). In this embodiment, the first motor 151 is a stepper motor which, as is well understood in the art of stepper motors, moves a predetermined amount in response to each voltage pulse applied to it from its driver 141. The belt drive mechanism 220 also includes the sensor 161 which senses when the etching head 130 is located in a fixed reference position along the scanning guide rail 230. The total number of steps from one extreme position of the etching head 130 to the other along the scanning guide rail 230 is precalculated or pre-measured and stored in the control unit 110. The reference position is also stored in the control unit 110 in terms of the number of steps from the reference position to each of the extreme positions of the etching head along the scaling rail 230. By keeping a record of how many voltage pulses are applied to the stepper motor 151 since it was last in the reference position, the position of the etching head along the scanning guide rail 230 is known to the control unit 110 at any time.

The etching apparatus 10 also includes feeding rollers 241, 242 which are driven by the second motor 152 and which operate to feed the printed circuit board 250 past the etching head under control of the control unit 10. Located above the first and second feed rollers 241, 242 are first and second cooperating sets of mini rollers 245, 246 which act to locate the PCB 250 securely against the first and second feed rollers 241, 242 respectively.

In the present embodiment, the second motor 152 is also a stepper motor and the distance by which PCB 250 is moved in the sub-scanning direction for every step of the motor 152 is pre-calculated or pre-measured and thus known to control unit 110. Additionally, the width and length of the PCB 250 is entered by a user into personal computer 20 and this information is communicated to, and thus known by, control unit 110. Mechanical guide means (not shown) which are expandable, about a fixed central point, to accommodate PCB's of different widths, ensure that the location of the PCB in the scanning direction is also known to the control unit 110. Furthermore, the second sensor 162 acts to detect the leading edge of PCB 250 as it passes between the first feed roller 241 and the first co-operating set of mini rollers 245; the second sensor 162 also detects when the trailing edge of PCB 250 passes beyond the rollers 241, 245. By counting the number of voltage pulses applied to the second motor 152 after detecting the leading edge of PCB 250, the control unit 110 knows the position of PCB 250 with reference to the etching head 130 at any time after detecting the leading edge. The detection of the trailing edge can be used to detect any errors in the system since the control unit can predict when the trailing edge should be detected and compare this with when the trailing edge actually is detected. Any discrepancy detected in this way is communicated by the control unit 110 to the personal computer 20 which can then notify the user.

In the present embodiment, the etching head 130 is removable and replaceable by a user of the device. Furthermore, the type of etchant to be used may be selected by the user in dependence on the material to be etched. To this end, a number of different etching heads 130 are available to the user with different etchants contained in the reservoirs 131 thereof. In order to select the desired etchant, the user installs the appropriate etching head 130 with the desired etchants stored in the etchant reservoir 131 thereof. This arrangement makes it very easy to etch different materials by simply swapping between different etching heads. As such, there is no need to wait for a large batch of jobs requiring an unusual etchant to form before swapping to a different etchant, and it is thus easy to perform one-off etchings to form a single prototype even if an unusual etchant is required to do this.

In the present embodiment, the etching head 130 has a single nozzle, the structure of which is shown in greater detail in FIG. 3. In particular, FIG. 3 is a cross-sectional diagrammatical view through nozzle 300 and the printed circuit board 250 so as to show the first copper layer 251, the substrate layer 252 and the second copper layer 253. As shown, droplets 310, 314 of etchant are selectively ejected from the nozzle 300 (in accordance with the voltage pulses applied to the etching head 130 by the head driver 120) onto the first copper layer 251 as the etching head 130 passes over the PCB. In the present example, the etchant used is ferric chloride.

In this embodiment, the nozzle 300 includes a glass capillary 320, the internal diameter of which tapers inwardly along its length in the direction of an outlet end 322 thereof to form a nozzle outlet 325 having a diameter of the order of tens of microns. The glass capillary 320 is mounted within a hole 332 formed within an etchant supply layer 330 which is porous to enable etchant to travel there through from the etchant reservoir 131. The glass capillary 320 is fixed in place by means of a layer 340 of epoxy resin which extends from the etchant supply layer 330 in a direction towards the nozzle outlet 325 (i.e. downwardly as shown in FIG. 3). Mounted on the other side of the etchant supply layer 330 (i.e. above the etchant supply layer 330 as shown in FIG. 3), is a chamber forming layer 350 made of glass and having a substantially circular opening 352 formed therein substantially in registry with the capillary but having approximately three times the diameter of the capillary. Mounted on the other side of the chamber forming layer 350 (i.e. above the chamber forming layer 350 as shown in FIG. 3) is a covering layer 360 which is also made from glass. The opening 352 within the chamber forming layer 350 combines with the interior of the glass capillary 320 to form an etchant holding chamber 370. Mounted on the side of the covering layer 360 facing into the etchant holding chamber 370 is an electro-thermal transducer element 380 which is formed from a resistive element 382 having two conductive tracks 384, 386 connected thereto supplying current through a resistive element 382. The conductive tracks 384, 386 have a low electrical resistance compared to the resistive element 382 so that when a potential difference is applied across the conductive elements 384, 386 and the resistive-element 382, the resulting current which flows through the elements 382, 384, 386 causes the majority of heat generated by the current flow to be generated at the resistive element 382.

Therefore, in operation, when the control unit 110 detects that the nozzle 300 is located over an element of the medium to be etched 251, it sends an instruction to the etching head driver 120 which causes the etching head driver 120 to apply a voltage across the conductive elements 384 and 386. This causes the heating of the resistive element 382 which in turn causes a vapour bubble to be formed in the etchant within the etchant holding chamber 370 adjacent to the resistive element 382. The formation of this vapour bubble rapidly raises the pressure within the etchant holding chamber 370 which in turn causes etchant to be ejected through the nozzle outlet 325. When the voltage applied across the resistive element 382 is removed, the vapour bubble collapses reducing the pressure within the etchant holding chamber 370 which stops the ejection of the etchant from the nozzle. Therefore, by controllably applying a short voltage pulse across the electrodes 384 and 386, droplets of etchant can be ejected from the etchant head in a controlled manner. Upon impacting the surface 251 of the PCB, each droplet 310 adheres to the surface 251 in an approximately hemispherical shape and etches away a portion 312 of the surface 251 on which the droplet 310 is deposited. Whilst droplets of etchant 310, 314 are being ejected from the nozzle 300, the entire etching head 130 is traversed along the guide rail 230 in a scanning direction (to the right as shown in FIG. 3). The movement of the etching head 130 in the scanning direction and the PCB 230 in the sub-scanning direction and the timing of the ejection of droplets of etchant are all controlled by the control unit 110 so as to deposit droplets of etchant onto the PCB 250 in accordance with the etching pattern communicated by the personal computer 20.

Discussion of the First Embodiment

The above described embodiment has the significant benefit of being able to employ well proven and readily available apparatus originally intended for conventional ink jet printing. In particular, a conventional ink jet print head cartridge may be adapted for use as the etching head 130 by replacing all ink contained in the print head cartridge with a suitable etchant. In such a case, an etching apparatus can be made by modifying a conventional commercially available ink jet printer such as a DeskJet Model 1120C drop-on-demand thermal ink jet printer produced by Hewlett Packard in conjunction with a model 51645A black print cartridge (also produced by Hewlett Packard) modified by removing the ink and replacing it with, for example ferric chloride etchant. Such an etchant apparatus can then be controlled by a conventional PC in which the conventional printer driver for the printer used to form the etching apparatus is installed, provided that the user ensures that the pattern to be etched is represented as a black and white bit map in which black portions correspond to portions to be etched and white portions correspond to regions of the medium which are not to be etched. Upon initiating a print command, a “blank” printed circuit board is fed to the etching apparatus (the width and length of the printed circuit board previously having been notified to the personal computer as the page size to be printed on). In order to prolong the useful life of the etching head, a maintenance station forming part of the conventional ink jet printer can be removed. Furthermore, with the etching apparatus formed in this manner, it is necessary to pass the printed circuit board to be etched through the etching apparatus a number of times to enable a sufficiently large amount of etchant to be deposited onto the printed circuit board in the appropriate places to completely etch through the top copper layer 251.

The performance of the etching head 130 rapidly deteriorates as the etchant consumes metallic parts of the etchant head which come into contact with the etchant. In particular, the conductive elements 384, 386 and the resistive element 382 are rapidly consumed by the etchant. It is therefore necessary to replace the etching head 130 on a regular basis (e.g. at least after the etching head 130 has been used to etch patterns into a small number of printed circuit boards). Similarly, any other metal parts within the etching apparatus as a whole will be attacked by the etchant since an etchant mist tends to be formed together with each droplet and this will be dispersed around the entire etching apparatus. At particular risk from this attack, are the guide rail 230 and the bearings by which the carriage 210 is slidably mounted onto the guide rail 230.

In the present embodiment, after the PCB 250 has been passed through the etching apparatus a few times, products of etching from earlier passes can form an etchant resistive layer which prevents further etching of the protected metal surface. This can significantly reduce the amount of metal etched by each new droplet of etchant deposited onto the PCB and can reduce the accuracy with which selected portions of the PCB 250 are etched.

Also, in the present embodiment, the PCB 250 is moved past the etching head in the sub-scanning direction. This is acceptable for PCB's and the like which are relatively thin and light and have a rectangular shape. The second embodiment (to be described below), however describes an etching apparatus in which the medium to be etched is held stationary and instead the etching head is moved both in the scanning and sub-scanning directions so as to enable the etching head to pass over the entire surface of the medium to be etched as before.

Embodiment 2

FIG. 4 is a diagrammatical perspective view of the arrangement of mechanical parts of an etching apparatus 400 according to a second embodiment. The electronic arrangement used to control the mechanical parts is substantially the same in the first embodiment and will not therefore be described again.

As shown, the mechanical components of the etching apparatus 400 include an etching head 410, including an etching reservoir 411, mounted on a carriage 415. Also mounted on the carriage 415 in the present embodiment is a cleaning head 420 which cleans the surface of the medium to be etched immediately prior to ejecting etchant thereon. The cleaning head 420 (which is described in greater detail below) removes any unwanted byproducts of earlier etching (i.e. from previous passes of the etching head over the medium to be etched) as part of this cleaning process. This is particularly useful where the surface must be regularly cleaned to prevent a protective layer forming over the surface to be etched which would prevent further droplets deposited on the surface from successfully etching the protected surface.

The carriage 415 is carried on a first guide rail 430 and, in this embodiment, a second guide rail 435 over which a guiding flange 437, forming part of the carriage 415, travels. The carriage 415 is propelled back and fourth along the guide rails 430, 435 in a scanning direction indicated by arrow E by means of a drive belt mechanism 440. The drive belt mechanism 440 includes a drive belt 441 supported around first and second pullies 444 and 446. The first pulley 444 is driven by a belt drive motor 448. The scanning guide rails 430, 435 and drive belt mechanism 440 are mounted on first and second supports 451 and 452 which are mounted for movement in a sub-scanning direction, indicated by arrow F, on first and second sub-scanning guide rails 453 and 454. In this way, the medium 250 to be etched may remain stationary, while the etching head 410 is passed over the entire surface of the medium.

In this embodiment, each of the supports 451, 452 includes a pinion 455 rotatably mounted to its respective support 451 which is driven by a pinion motor 457 controlled by the control unit. The teeth of the pinions 455 engage with corresponding teeth formed in the respective sub-scanning guide rails 453 and 454. Thus, the guide rails 453, 454 constitute racks which cooperate with the pinions 455 to form rack and pinion arrangements.

In the present embodiment, exposed metallic parts are kept to a minimum. Thus, the guide rails 430, 435, 453, 454 are all made out of a material which is resistant to metal etchants. In the present embodiment, the guide rails 430, 435, 453, 454 are made out of a rigid plastics material formed by injection moulding. Furthermore, the bearings used for mounting the carriage onto the first guide rail 430 are also made of plastics material; such bearings are well-known especially in the art of food processing machinery. Additionally, the motors are all encased within a cover made from etchant resistant material such as plastics material. Similarly, all electronic parts are shielded from the etchant mist by encasing them within a shield casing and ensuring that all wires running from the electronics to, for example, the etching head 410, the cleaning head 420 and the motors 448, 457 are encased within plastics material.

In the present embodiment, the cleaning head 420 is positioned to be immediately in front of the etching head 410 whilst the etching head 410 is scanning across the medium to be etched and depositing etchant (i.e. when the etching head 410 is scanning across the medium from left to right as viewed in FIG. 4). Once the etching head 410 has scanned completely across the width of the medium to be etched 250 (such a traverse is hereinafter referred to as a swathe), the carriage 415 is quickly traversed back to the far left hand side of the medium to be etched whilst at the same time the first and second supports 451, 452 are driven in the sub-scanning direction to bring the cleaning head 420 and etching head 410 into a position ready to etch a new swathe across the medium to be etched. In this embodiment, whilst the carriage is moving from the end of one swathe to the being of the next, no etchant is ejected from the etching head 410 and the cleaning head 420 is switched off.

In this embodiment, the cleaning head 420 includes a spray (not shown) for spraying cleaning fluid, in a thin jet, across the width of a swathe; a brush (not shown) for brushing the cleaning fluid and any dirt or waste products from previous etching together with the cleaning fluid back off the surface of the medium and a vacuuming device (not shown) for removing waste from the brushing means and for sucking any remaining waste products from the surface of the medium. In the present embodiment, the cleaning head 420 further includes a blower (not shown) for blowing warm dry clean air onto the surface of the medium to be etched immediately behind the vacuuming device to ensure that the surface presented to the etching head 410 following behind the cleaning head 420 is clean and dry.

In the present embodiment, the etching head 410 uses piezoelectric drop on demand technology instead of the thermal drop on demand technology employed in the first embodiment. FIG. 5 is a diagrammatical enlarged cross-sectional view through a column of nozzles formed within the print head 410 of the second embodiment showing two such nozzles 500, 510. In the present embodiment, each nozzle 500, 510 includes a glass capillary 520, 525 whose internal diameter tapers towards the outlet end thereof 521, 526, to form a nozzle outlet 522, 527 having a diameter of a few tens of microns across. Each capillary 520, 525, is mounted within a hole 532, 534 formed within an etchant supply layer 30. As before, the etchant supply layer 530 is porous to enable etchant to flow from the etchant reservoir 411 to the nozzles 500, 510. The glass capillaries 520, 525 are held in place by a layer 540 of epoxy resin attached to the underside of the etchant supply layer 530 as before. Mounted above the etchant supply layer 530 is a chamber forming layer 550 in which openings 552, 554 are formed which combine together with the interior of the glass capillaries 520, 525 to form nozzle chambers 572, 574. Mounted above the chamber forming layer 550 is a covering layer 560 which is also formed from glass but which is relatively thin (e.g. approximately 50 microns in thickness) so as to permit it to act as a deflection plate 560 as described below. The thicknesses of the covering layer 560 should be about 30 to about 100 microns, depending on the specific material selected for the layer and its modulus of elasticity. Mounted on the surface of the covering layer 560 opposite to the chamber forming layer 550 are a plurality of piezoelectric elements 582, 584 each of which is substantially in register with a corresponding glass capillary 520, 525. Each piezoelectric element 582, 584 is securely bonded to the covering layer 560 and is activated by applying a voltage across it (electrodes are attached to each piezoelectric element in a manner well-known in the art of piezoelectric elements for this purpose). Upon activation, the piezoelectric element 582, 584 expands (by an amount dependent upon the voltage applied across the electrodes and the configuration of the piezoelectric element) in the plane parallel to the plane of the covering layer 560. Since the covering layer 560 to which the piezoelectric element is bonded resists expanding in this plane, both the piezoelectric element and the covering layer to which it is bonded deflect out of the plane. This causes the volume of the chamber 572, 574 to expand thereby reducing the pressure within the chamber. Upon deactivation of the piezoelectric element the covering layer resumes its original state thereby contracting the volume within the chamber 572, 574, as a result of which etchant is ejected from the nozzles 522 and 527. Therefore, by controllably activating and deactivating the piezoelectric element, droplets of etchant can be controllably ejected from the etchant head onto the medium to be etched.

In order to activate the piezoelectric elements 582, 584, a fairly high potential difference needs to be applied across the elements (e.g. approximately 60 volts) however only a small “current” is drawn at this voltage so a similar amount of power is consumed for each activation as for the thermal drop on demand embodiments discussed above. In order to provide the high potential differences, suitable high voltage regulation circuitry is included within the electronics associated with the etching apparatus 400.

From the above description of the etching head 410 of the present embodiment, it will be appreciated that the etchant does not come into direct contact with any metallic or metalised parts (the only metalised parts within each nozzle are the electrodes connected to the piezoelectric elements 582, 584 and conductive tracks leading from those electrodes). In this way, the etching head 410 is substantially resistant to the deleterious effects of the etchant.

Discussion of the Second Embodiment

The cleaning head 420 of the second embodiment is removable so that for certain applications it need not be used. The length of time taken for an etching reaction to occur and the frequency with which the surface of the medium to be etched needs to be cleaned will vary depending on the etchant used and the material of the medium to be etched. Thus in some cases it may be more appropriate to periodically stop etching and to clean the medium to be etched by hand, or it may not be necessary to clean the medium at all during the entire etching process.

It is also possible to employ established ink-jet technology to provide the etching head for the present embodiment. For example, a model 64 ID2 64 nozzle printhead supplied by Inkjet Technology Inc. could be used to provide the etching head. However, it may be desirable to produce a similar etching head but having a larger drop size than the 120 picolitre drop size provided by the 64 ID2, for example, having a size of 1000 picolitres or greater. A drop size of between 500 picolitres to 5000 picolitres may be particularly suitable for some applications.

One application for the etching apparatus 400 of the second embodiment is in the machining of small thin metallic parts. Such parts may be formed from, for example, steel for which a suitable etchant is again ferric chloride. A typical such part may be manufactured from a steel billet having a thickness of approximately one millimetre (or one thousand microns). The etching head 410 of the second embodiment has a planar resolution of approximately 600 dots per inch which corresponds to a droplet size of approximately 80-120 pico-litres (i.e. having a diameter of approximately 50-60 microns). Such a droplet will typically etch to only, a very shallow depth (i.e. less than one micron) on average per droplet. Thus, the depth resolution is approximately continuously variable depending upon the average amount of etchant deposited per unit area of the metal surface of the billet in each pass of the etching head over the billet.

In order to reduce the etching time by half, the apparatus could be modified to simultaneously selectively eject etchant onto both sides of the billeted steel to be etched by having a second etching head and associated mechanics arranged opposite to the first set to etch from the “underneath” side of the steel billet. The droplets of etchant are sufficiently small that they may easily be ejected against the force of gravity, and once they have hit the surface of the billet they adhere to the surface with sufficient attraction that they do not run or drip off the billet.

Embodiment 3

FIG. 6 is a diagrammatical perspective view of the arrangements of mechanical parts of an etching apparatus 600 according to a third embodiment. The etching apparatus 600 is substantially similar to the etching apparatus 400 of the second embodiment except that instead of having a cleaning head 420 mounted together with the etching head 410, the cleaning head 620 is mounted on a separate set of supports 651, 652. As shown, the first and second cleaning head supports 651, 652 are mounted on the first and second racks 453, 454 so as to permit the cleaning head 620 to be controllably moved in the sub-scanning direction indicated by arrow F over the entire surface of the medium to be etched to permit periodic cleaning thereof. In this embodiment, the cleaning head extends across the entire width of the medium to be etched. There is therefore no need to scan the cleaning head in the scanning direction. As in the case of the first and second support 451, 452 supporting the belt drive mechanism 440, the first and second cleaning head supports 651, 652 are driven along the racks 453, 454 with pinion motors 657 similar to the pinion motors 457 used to drive the first and second supports 451, 452 which support the drive belt mechanism 440.

During operation of etching apparatus 600, the first and second supports 451, 452 supporting the belt drive mechanism 440 periodically move beyond the medium 250 away from the cleaning head 620 to permit the cleaning head 620 to be moved over the surface of the medium to be etched 250. The cleaning head 620 includes a spray for spraying cleaning fluid onto the surface of the medium 250, a brush for removing unwanted materials from the surface and a vacuuming device for removing both the unwanted material from the brushing and any further waste material remaining on the surface. In the present embodiment, the cleaning head 620 also includes a hot air blower for blowing hot air onto the surface of the medium to ensure that it is both clean and dry after the cleaning head 620 has finished a cleaning operation. In the present embodiment, each cleaning operation includes a first pass over the medium 250 in the direction towards the etching head in which the spraying, brush and vacuuming device are employed and a second pass over the medium moving in the direction away from the etching head 410 during which the hot air blower is used to blow hot air onto the surface of the meeting medium. At the end of the cleaning operation, the cleaning head is returned to a home position where it is out of the way of the etching head 410 and associated mechanisms 440, 451, 452.

The determination of when a cleaning operation is performed is controlled in the present embodiment by the control unit in accordance with an algorithm which provides that after a predetermined number of complete passes by the etching head 410 over the surface of the medium 250 such as, for example, fifty such passes, the etching head 410 and associated mechanisms 440, 451, 452 are translated out of the way of the cleaning head 620 and a cleaning operation is performed. In this embodiment, the predetermined number of complete passes before a cleaning operation is performed can be programmed by a user of the host PC 20. In this way, the user may vary the number of complete passes by the etching head over the medium to be etched before a cleaning operation is performed in dependence on the particular parameters of the current etching process (e.g. the temperature at which etching is performed, the type of etchant used and the material of the medium to be etched).

Embodiment 4

FIG. 7 is a diagrammatical perspective view of the arrangement of the mechanical parts of an etching apparatus 700 according to a fourth embodiment. The fourth embodiment is similar to the second and third embodiments except that the automatic cleaning head has been removed and a mechanical arrangement has been provided whereby the etching head 410 may be raised and lowered in a vertical direction as well as being translated in both the scanning and sub-scanning directions. In this embodiment, if the medium being etched is to be cleaned, then this is done manually.

In this embodiment, the etching head 410 is removably mounted within a hanging carriage 715 which is rigidly attached to a sliding bar 717 which is slidably mounted within a scanning carriage 716. The sliding bar 717 has teeth formed therein for co-operating with a pinion wheel (not shown) mounted within the sliding carriage 716. The pinion wheel mounted with the sliding carriage 716 is controlled by the control unit of the etching apparatus 700 to raise or lower the sliding bar 717 and thus the hanging carriage 715 and etching head 410. The sliding carriage 716 is slidably mounted on a first guide rail 730 by means of plastic bearings and is also supported by a second guide rail 735 via a slide 737 which slides along the second guide rail 735.

In this embodiment, the sliding carriage 716 is controllably moved back and forth in the scanning direction indicated by arrow E by means of a belt drive mechanism 740. The belt drive mechanism 740 is similar to the belt drive mechanism 440 of the second and third embodiments and will not therefore be described again.

As in the second and third embodiments, all parts which are exposed to the atmosphere and therefore at risk of being attacked by etchant mist are either formed from etchant resistant material such as plastics material or are shielded by an etchant resistant casing.

The fourth embodiment is particularly suited for etching somewhat thicker metal items to be etched such as the steel billet 750 illustrated in FIG. 7 which is being etched to form a mould tool for use in producing injection moulded casings for a consumer product. The accuracy with which a drop of etchant can be fired from a nozzle of etching head 410 to the surface of the metal item to be etched can be reduced where the distance between the outlet of the nozzle and the surface of the medium is greater than about three millimetres; such distances occur, for example, within the trough of a mould tool (such as mould tool 750) for a typical consumer product having dimensions greater than a few millimetres. To mitigate this problem, the control unit of the etching apparatus 700 controls the height of the etching head 410 by raising and lowering the sliding bar 717 such that the etching head 410 dips into the trough as it scans over the trough to try to maintain as close a distance as possible between the outlets of the nozzles on the etching head 410 and the surface of the item 750 onto which droplets of etchant are to be deposited. To enable the control unit of the etching apparatus 700 to determine the optimum vertical position of the etching head 410, a distance sensor (not shown) is mounted onto the sliding carriage 716. The distance sensor is operable to sense the distance between the medium surface and the distance sensor shortly ahead of the current location of the etching head 410 as the etching head 410 scans across from left to right depositing etchant on the medium surface. In the present embodiment, the distance sensor is an inductive sensor.

The control unit of the etching apparatus 700 constantly monitors the distance readings from the distance sensor to determine what the correct vertical position should be for the etching head 410 to ensure that it is as close as possible to the surface of the item 750 without any part of the etching head 410 actually touching the surface of the item 750.

In this embodiment, the personal computer 20 generates a CAD model of the wanted shape to be produced and then generates data representative of which portions of a billet, which is to be used as the starting etchable material, should be removed in order to generate the wanted shape. This data is then represented as a series of layers of elements of volume (having a cuboid shape) in which each layer is one element thick, and each element corresponds to an acceptable resolution for the purposes of digitising the wanted shape. In the surface or planar dimensions, this resolution is limited to the maximum member of dots per inch achievable by the apparatus, (eg 600 dots per inch) but coarser resolutions (e.g. 100 dots per inch) may be used instead if appropriate. In the depth direction, a desired resolution is chosen and then the etching apparatus is operated to achieve this; for example, if each volume element is set as having a depth of 1/600 of an inch, then the number of passes and an appropriate ejection strategy required to etch to such a depth is determined. Each layer is then converted into a bitmap in which volume elements which fall within a portion of the billet to be removed are each designated as a remove bit (by setting the bit to a “1”) and every other bit is designated as a do-not-remove bit (by setting the bit to

The personal computer 20 then transmits the bit-maps one at a time to the etching apparatus 700 together with an indication of the height and width (in the plane of the surface of the etchable material) corresponding to each bit and how many complete passes by the etching head over the billet are required (while using the same bitmap) per layer. When a layer has been completed and the bitmap for the next layer is downloaded and used to control the ejection of etchant for each pass during the next layer. The etching apparatus uses this information to control the ejection of etchant droplets at the appropriate positions of the etching head 710 in the scanning and sub-scanning directions. This is continued layer-by-layer, until the etching process is finished, whereupon the personal computer 20 informs the user that etching has finished.

In the present embodiment, the distance sensor readings from the distance sensor are also communicated back to the personal computer 20 together with information about the number of complete passes which have been made over the item to be etched by the etching head 410. The personal computer 20 then uses this information to check that the actual current shape of the item being etched conforms with the expected shape of the item being etched for any given number of complete passes of the etching head 410 over the item 750. If any disagreement is found between the measured shape and the expected shape, the personal computer 20 calculates a new set of etching instructions to ensure that the final shape of the item 750 corresponds to the desired final shape.

Discussion of the Fourth Embodiment

An example of how the personal computer 20 can use the information from the distance sensor to alter the etching instructions issued to the etching apparatus 700, will now be given. In the case that a square trough with approximately vertical sides is to be formed approximately one centimetre deep with a width and length of 2 cm within a steel billet which is two centimetres deep, by ten centimetres long, by ten centimetres wide, the user instructs the personal computer 20 to use a resolution of 0.2 mm or 200 microns in each direction (i.e. the volume elements are cubes with 200 micron sides). The personal computer 20 therefore generates 50 layers of 200 microns thickness each (total thickness of 1 cm) and 500 by 500 bitmaps. It then determines an ejection, scanning and cleaning strategy (the personal computer will periodically stop the etching apparatus from etching and advise the operator to the clean etchable material; on completion of cleaning, the operator informs the computer 20 that cleaning has finished) for depositing on appropriate amount of etchant on each volume element to completely etch it away. For example, it might determine to deposit N thousand droplets per volume element per pass and might determine, that at this rate, for a given assumed etching rate, one hundred passes are required to etch each layer. On this basis, the personal computer 20 initially generates fifty bitmaps each corresponding to a single layer and requiring one hundred passes over the item to be etched 750 with the same bitmap etching data for each pass (and in this case also for each layer, the etching data corresponding to the square surface-projection size of the trough to be etched of 2 cm by 2 cm). If after one hundred passes the distance sensor determines that a trough having a depth of 250 microns has already been formed, the personal computer 20 is able to calculate that the actual number of passes required to etch off each layer is in fact eighty passes per layer and not one hundred passes per layer.

The rate at which etching occurs is dependent to an extent on the temperature at which the etching occurs. Embodiment 5, described below, includes a heater for heating the etchant and/or the item to be etched up to a desired temperature.

Embodiment 5

FIG. 8 is a diagrammatical perspective view of the arrangement of the mechanical parts of an etching apparatus 800 according to a fifth embodiment. The fifth embodiment is similar to the second, third and fourth embodiments except that the belt drive and rack and pinion mechanisms for traversing the etching head in the scanning, sub-scanning and vertical directions are replaced in the fifth embodiment with a robotic arm structure 840. The robotic arm structure 840 is able to steer the etching head 810 around irregular surfaces formed in the item 850 to be etched.

Additionally, in this embodiment, the etching head 410 has been replaced with a much smaller etching head 810. The etching head 810 corresponds approximately to the active portion of etching head 410, there being no reservoir for storing etchant included in the etchant head 810. Instead, a separate etching reservoir 711 is attached to a part of the robotic arm structure 840 where it is not at risk of hindering the movement of the etchant head 810, and a feeder tube 812 supplies etchant from the etchant reservoir 811 to the etching head 810. Also, in this embodiment, the etching reservoir 711 includes a controllable heater which heats the etchant stored in the etchant reservoir 711 in order to maintain the etchant at a selected elevated temperature.

An example application for the etching apparatus 800 is for etching fine surface detail patterns into the appropriate surfaces of mould tools so that injection moulded products made using the mould tools, will have a corresponding fine structure surface detail. Conventionally, such surface detail would be etched into the mould tools using photochemical machining; however, this is awkward because photomasks need to be carefully positioned against an irregularly shaped surface, the general or macroscopic shape of the mould tools having been formed using an alternative method such as electro-discharge machining, or high speed machinery.

The electronics associated with the etching apparatus 800 are similar to those of the second embodiment except that the control unit now has a larger number of motors to control (corresponding to each of the motors used in driving the robotic arm structure 840). However, techniques for controlling robotic arm structures are well-known and will not be described here.

FIG. 9 is a flow chart illustrating the steps involved in manufacturing a consumer product which includes injection moulded parts formed from plastics material.

The start of the method is indicated by start step S5. The first stage in the process is to generate, in step S10, using Computer Assisted Design (CAD) techniques, accurate computer models of the mould parts which will be used to manufacture the end consumer product. The method then continues to step S20 where CAD models of the mould tools required to form the mould tools are generated and then converted, into negatives. Each negative is represented by data representative of a series of thin layers of cuboid volume elements. Each layer is represented by a bit map, where bits corresponding to volume elements of material which is to be removed, are set as etch-bits (by making their value 1) whilst bits corresponding to volume elements of material to be left are set as do-not-etch bits (by making their value 0). Each layer has a thickness determined in accordance with an acceptable resolution and corresponds to the average depth of metal removed during a member of complete passes of the etching head over the billet to be etched in respect of those areas in which etchant is deposited. The method then continues to step S30 where a user loads up the etching apparatus both with an appropriately sized and shaped billet of metal (typically steel) and with sufficient etchant of the appropriate type for the metal billet. The method then proceeds to step S40, where the etching is performed. To do this, each layer of the billet is etched in accordance with bitmaps. Once all of the layers have been selectively etched the etching process is finished and the completed mould tool is removed from the etching apparatus.

On completion of step S40, the process moves to step S50 where it is determined if all of the mould tools required for manufacturing the end product have now been formed. If more mould tools need to be formed, control is passed back to step S30 and the etching process is repeated for the next mould tool. Once all of the mould tools have been formed the process moves to step S60 where the mould tools are installed into a suitable injection moulding machine (not shown). Upon completion of step S60, the process moves to step S70 where injection moulding is performed one or more times using the installed mould tools to generate injection moulded parts. Finally, the process moves onto step S80 where the final end products are assembled using the moulded parts formed in step S70. The process then ends as indicated by end step S85.

Variations

It will be appreciated that a number of variations to the above described embodiments are possible. For example, features found in any of the above described embodiments may be incorporated into any other of the above described embodiments.

In the above described embodiments, the etchant supply layer 530 is made from porous ceramic material. However, in place of the porous material, the etchant supply layer 530 could be formed from glass with numerous small etchant supply channels formed therein. The etchant supply channels should have dimensions to ensure that the etchant supply channels have a similar or greater impedance to the flow of etchant compared to the nozzle outlet, so that droplets of etchant can be ejected without having to use excess force.

In the fourth embodiment, the etching head 410 has a large body immediately above the small 1 cm³ active part of the head for containing the etchant reservoir 411. However, an etching head which is designed for hugging the contours of an uneven surface could be used instead. Such an etching head could have a face in which the nozzle outlets are formed with as small a surface area as possible and steep sided walls leading to the reservoir in which the etchant is stored. Preferably, the surface area of the face in which the nozzle outlets are formed would be of the order of one centimetre squared. The length of the steep sided walls connecting the face in which the nozzle outlets are formed to the etchant reservoir preferably ranges from about two centimetres to about ten centimetres and an etching head is chosen by a user with appropriately sized side walls depending on the thickness of the item to be etched such that the etchant reservoir is always located above the upper surface of the item to be etched. Alternatively, the etching head can be completely removed from the etchant reservoir with a small etchant feeding pipe connecting the two together.

Furthermore, a number of the above described embodiments employ a rack and pinion mechanism for moving one or more parts relative to others. These mechanisms could be replaced by any other equivalent mechanism such as a belt drive mechanism, Similarly, where the embodiments employ a belt drive mechanisms, this could be replaced by any equivalent mechanism such as a rack and pinion mechanism.

The above described embodiments illustrate two different mechanisms for selectively depositing etchant onto a medium, namely a thermal drop-on-demand mechanism and a piezoelectric drop-on-demand mechanism. Both of these mechanisms are known in the art of ink-jet printing and many variations to the basic operation of these mechanisms are known and may be usefully applied to the above described embodiments. For example, instead of generating a bubble directly in the etchant, a less corrosive working liquid could be employed, with a membrane separating the working liquid from the etchant. Similarly, in the piezoelectric mechanism the piezoelectric elements could be replaced with bimorphs which are well-known arrangements in which two piezoelectric elements are bonded together and arranged so that when a voltage is applied to them one element expands and the other contracts or vice-versa. This causes a deformation of the bimorph which can be used to drive etchant into and out of an etchant chamber. Alternatively, a piezoelectric element could be shaped as a rod and caused to expand and contract along its length. This movement can then be used to pump etchant in a piston-like manner.

Furthermore, instead of using drop-on-demand mechanisms, continuous drop mechanisms could be employed, using either a thermal bubble or a piezoelectric driven modulation to form the drops, and selectively charging each drop and controlling its trajectory thereafter by means of an electric field so as to accurately deposit a droplet on the item to be etched.

Using such a system, it is possible to apply relatively large continuous pressure on the etchant which can increase the distance by which a droplet may be ejected and accurately deposited onto a target surface.

In the fourth and fifth embodiments, the height of the etching head is controlled to enable the distance between the outlets of the nozzles and the target surface onto which the droplets are to be deposited to be maintained as small as possible. Alternatively, or in addition, an etching head can be used which is able to accurately eject or throw droplets a relatively long way (e.g. of the order of a few centimetres). Furthermore, it may be possible to adjust the distance by which each droplet can be accurately thrown by adjusting the level of the control voltage (and thus the energy) applied to activate each respective nozzle.

In the fourth embodiment described above, etching data for driving the etching apparatus 700 is generated, by the personal computer 20 which controls the apparatus, by assuming that each droplet of etchant will remove a fixed volume of the starting piece of material to be etched, with feedback provided by a distance sensor to provide on-the-fly corrections as necessary. However, this arrangement can be improved by employing, either in addition to or instead of the feedback arrangement, an algorithm which accounts for “boundary-effects”. Boundary-effects is a term used to describe the different response to droplets of etchant by the etchable material at a boundary between an etched portion and an unetched portion compared to the average response to droplets of etchant within an etched position (i.e. everywhere apart from the boundaries).

To account for such boundary-effects, the algorithm can assume that each droplet of etchant will etch a different volume of material at a boundary, compared to the average volume of material removed by a droplet of etchant. Furthermore, some smoothing function may be used to gradually move from a “boundary volume element” size to an “average volume element” size as a function of distance from a boundary, etc. The appropriate values for such a smoothing function, including a suitable “boundary volume element” size, are best found using trial-and-error empirical experiments, bearing in mind the following factors which may have an influence: type of material to be etched, type of etchant, temperature, size of etchant droplets, depth of etching, etc. This information can then be used to vary the number of droplets deposited at or near a boundary, by varying the etching data accordingly.

Alternatively, the operation of the etching apparatus may be controlled to effectively increase (or reduce) the amount of etchant ejected per boundary volume element so that each boundary volume element does remain approximately the same size as a non-boundary volume element. A number of methods can be used to increase (or reduce) the amount of etchant ejected per volume element of etchable material to be removed. For example, the number of droplets ejected per scan over the same area may be varied; the frequency with which droplets are ejected over different areas may be varied; the speed at which the etching head is relatively moved over the item to be etched may be varied; the size of droplets ejected may be varied; the temperature of the etchant may be varied; or the concentration of the etchant may be varied.

To vary the concentration of the etchant, an arrangement is preferably provided between the active part of the etching head and the etchant reservoir which enables a controlled flow of water to be mixed up with the etchant (in over-concentrated form) just upstream of a heating element which can be used to heat the diluted mixture prior to its entering firing nozzles. This arrangement gives excellent control over the temperature of etchant from firing nozzles as well as ensuring a thorough mixture of the diluted etchant (from the turbulence caused by flow over heating element). For some applications it may be useful to cool the etchant. For this purpose, a cooling element may be used in place of or in addition to the heating element.

Alternative methods of accounting for boundary effects can be used and suitable algorithms for this purpose will be apparent to the reader based on the general principle of employing trial-and-error experiments to first observe the nature of the boundary effects and how they are impacted by varying different aspects of the etching process and thereafter controlling one or more aspects of the etching process to be different at boundaries to minimise the boundary effects during an etching process.

In order to reduce the impact of the generation of by-products of etching forming a protective layer over etchable material, which reduces the effectiveness of further etchant deposited on top of the protective layer, high frequency (e.g. sonic or ultrasonic frequencies), low amplitude vibrations may be applied to the item to be etched, in addition to or instead of performing cleaning. The vibrations may be imparted directly to the item to be etched by, for example, driving a motor with an eccentric element or a piezoelectric element connected to the item to be etched. A range of frequencies can be used, such as, for example, a combination of frequencies ranging from between 1 KHz to 100 KHz. Preferably the maximum amplitude of vibrations of the item to be etched is of the order of tens or hundreds of microns, but sufficient energy is used to cause the relative motion between the etchant and the etchable surface to be increased as a result of the vibrations.

There are a number of applications for the etching system as above described. For example, the etching system may be used to generate printing plates by selectively etching a thin layer out of a blank printing plate.

In addition to storing etchant within etchant reservoirs formed within the etching head, a separate vessel could be used to store much larger quantities of a particular etchant, with an automatic mechanism being provided for maintaining sufficient quantities of etchant within a currently utilised etchant reservoir within the etchant head by periodically topping it up from the separate vessel.

The number of nozzles formed in each head may be varied from as little as one to as large as 256 or more. Instead of scanning an etching head in a scanning direction, a medium-wide etching head could be used, thus avoiding the need to scan the etching head (except possibly in the sub-scanning direction—i.e. lengthwise over the medium). Similarly, a single large area etching head could be used without therefore requiring any relative motion between the etching head and the medium.

However, these embodiments are not preferred because of the expense of manufacturing a head having a large number of nozzles allocated close together, each of which is independently controllable. As an alternative, in order to increase the speed with which etching is performed, a plurality of etching heads (and possibly cleaning heads—cf. embodiment 2) may be used. A number of different arrangements of the etching heads could be useful, but one which multiple swathes are performed simultaneously may be particularly beneficial in speeding up the etching process.

In the described embodiments, the etching apparatus has very little “intelligence” and is largely controlled by the host personal computer 20. However, different configurations are possible. For example, a single stand alone device incorporating a user interface and sufficient “intelligence” to generate the bitmaps and scanning, ejection and cleaning strategies for a given CAD model of a wanted item and a starting billet. Such a device might include a device for reading portable storage media such as a floppy disk drive, etc. Also, the etching apparatus may be connectable to a computer network so that any other device connected to the network can operate the etching apparatus, etc.

In the above described embodiments, the etching system has been described as being useful for the formation of mould tools especially for injection plastic moulding (of thermoplastic materials). The etching systems are also equally applicable for the manufacture of mould tools for use in: die casting of, for example, metals such as aluminium or zinc; glass moulding of glasses and ceramics, etc; and dough moulding (of thermoset materials).

The above described embodiments include processes carried out by a processor, either within the control unit of the etching apparatus or within the host device such as pc 20. The invention also extends to computer programs, particularly computer programs on or in a carrier, adapted for putting the processes into practice. The program may be in the form of source code, object code, a code intermediate between source code and object code such as in partially compiled form, or in any other form suitable for use in the implementation of the processes. The carrier may be any entity or device capable of carrying the program.

For example, the carrier may comprise a storage medium, such as a ROM, for example a CD ROM or a semiconductor ROM, or a magnetic recording medium, for example a floppy disk or hard disk. Further, the carrier may be a transmittable carrier such as an electrical or optical signal which may be conveyed via electrical or optical cable or by radio or other means.

When the program is embodied in a signal which may be conveyed directly via a cable or other device or means, the carrier may be constituted by such cable or other device or means.

Alternatively, the carrier may be an integrated circuit in which the program is embedded, the integrated circuit being adapted for performing, or for use in the performance of, the relevant processes.

1. An etching system for forming an item having a desired shape or pattern from an initial piece of etchable material, said system comprising:
a reservoir of etchant;
an etching head having an output orifice in communication with said reservoir and means for controllably ejecting etchant out of the orifice onto the etchable material in response to a control signal;
means for receiving design data representative of the desired shape or pattern;
means for processing said design data
(i) to identify the location of the or each portion of said initial piece of etchable material to be removed by etching, and
(ii) from the or each identified location, to generate control signals for controlling the operation of the ejecting means; and
means for applying said generated control signals to said ejecting means in order to selectively eject etchant from said orifice onto said initial piece of etchable material to form said item with the desired shape or pattern.

2. The etching system of claim 1 wherein the reservoir includes a first opening to allow the etchant to flow out of the reservoir, and a second opening to allow replacement air to flow into the reservoir as etchant flows out of the reservoir.

3. The etching system of claim 1 or 2 wherein the reservoir includes an opening to allow etchant to flow out of the reservoir and is collapsable to permit the volume of the reservoir to reduce as etchant flows out of the reservoir.

4. The etching system of any preceding claim wherein the reservoir is formed from plastics material.

5. The etching system of any preceding claim further including means for controlling the temperature of the etchant.

6. The etching system of claim 5 wherein the means for controlling the temperature of the etchant comprises a heating means for heating the etchant prior to it being ejected, to within a desired temperature range.

7. The etching system of any preceding claim wherein the reservoir and etching head are integrally formed within a single cartridge unit.

8. The etching system of any preceding claim wherein the means for controllably ejecting etchant includes a means for applying pressure to the etchant to force it from the orifice.

9. The etching system of claim 8 wherein the means for applying pressure to the etchant includes an electro-thermal transducer for controllably generating a vapour bubble which acts to increase the pressure applied to the etchant.

10. The etching system of claim 9 including a working fluid in pressure communication with the etchant, and wherein the electro-thermal transducer is operable to generate a vapour bubble within the working fluid.

11. The etching system of claim 8 wherein the means for applying pressure to etchant includes a Piezo-electric element whose shape is controllably changeable to modify the pressure applied to the etchant.

12. The etching system of any preceding claim wherein the means for controllably ejecting etchant includes means for selectively charging droplets of etchant ejected from said orifice and means for controlling the the trajectory of charged droplets of etchant by the application of a variable electric field.

13. The etching system of any preceding claim wherein said etching head includes a controllable water inlet for introducing water at a controlled rate into an etchant stream flowing from said reservoir to said orifice, whereby the concentration of etchant ejected may be modified by modifying the rate at which water is introduced into the etchant stream.

14. The etching system of claim 13 wherein a heating element is located within the etchant stream in the vicinity of, or downstream, the water inlet.

15. The etching system of any preceding claim further comprising movement means for causing relative movement between the etching head and the etchable material.

16. The etching system of claim 13 wherein the movement means includes scanning means for causing reciprocal relative movement between the etching head and the etchable material along a scanning path.

17. The etching system of claim 16 wherein the movement means further comprises sub-scanning means causing reciprocal relative movement between the etching head and the etchable material along a sub-scanning path which is different from the scanning path, said scanning path and sub-scanning path lying approximately within a scanning plane.

18. The etching system of claim 17 wherein the sub-scanning path is substantially orthogonal to the scanning path.

19. The etching system of claim 17 or 18 wherein the movement means includes elevation means operable to move either or both of the etching head and the etchable material towards or away from the scanning plane.

20. The etching system of claim 19 wherein the elevatation means is operable to cause reciprocal relative movement between the etching head and the etchable material in an elevation path which is substantially orthogonal to both the scanning plane.

21. The etching system of any of claims 15 to 20 wherein the movement means is operable to move the etching head whilst maintaining the etchable material stationary.

22. The etching system of any of claims 15 to 20 wherein the movement means is operable to move both the etching head and the etchable material.

23. The etching system of any of claims 15 to 22 including one or more bearing members forming part of the movement means for allowing relative movement between the etching head and the etchable material, said one or more bearing members being formed from a metal-etchant resistant material.

24. The etching system of claim 23 further including one or more guide rails for supporting one or both of the etching head or the item to be etched via one or more bearing members for movement therealong, said one or more guide rails being formed from a metal-etchant resistant material.

25. The etching system of any of claims 15 through to 23 further including a distance sensor operable to detect the distance between said distance sensor and one or more locations on said piece of etchable material and to feed back information to the movement means to assist with moving the etching head and the etchable material relative to one another.

26. The etching system of any preceding claim further including means for determining the shape or pattern of the etchable material and means for feeding this information back to the means for processing said design data for periodically adjusting the control signals for controlling the operation of the ejecting means to prevent large deviations away from the desired shape or pattern.

27. The etching system of any preceding claim including means for receiving billet data representative of the size and shape of the initial piece of etchable material, and wherein the processing means includes means for comparing the billet data with the design data in order to identify which portions of said initial piece of etchable material should be removed by etching in order to derive the item having the desired shape or pattern.

28. The etching system of any preceding claim wherein said processing means is operable to generate a negative shape or pattern from said design data which identifies the location of the or each portion to be removed.

29. The etching system of claim 28 wherein said processing means is operable to divide said negative shape or pattern into a plurality of volume elements in which volume elements which fall substantially within a portion to be removed are designated as volume elements to be removed and the remaining volume elements are designated as volume elements to be kept.

30. The etching system of any preceding claim wherein the etching system is operable to form the desired shape or pattern by applying etchant to the etchable material in phases each of which removes etchable material to a predetermined depth.

31. The etching system of claim 30 when depending on claim 29 wherein each volume element has a depth which corresponds to the predetermined depth of etchable material which is removed in each phase.

32. The etching system of any preceding claim further including means for identifying a boundary between a portion of said etchable material, which is not to be removed by etching and a portion of said etchable material, which is to be removed by etching, and for controlling the etching system to deposit a different amount of etchant per volume of etchable material to be removed in the vicinity of said boundary compared to the amount of etchant per volume of etchable material to be removed deposited away from said boundary.

33. The etching system of any preceding claim further including vibrating means for causing said etchable material to vibrate whereby the speed with which newly deposited etchant comes into contact with unreacted etchable material to be etched is increased.

34. The etching system of any preceding claim wherein said system is operable to deposit etchant onto the surface of said etchable material at a rate which is greater than one tenth of a litre per square metre per minute.

35. An etchant reservoir comprising the technical features of any of claims 2 to 5.

36. An etching head cartridge having an etching head and reservoir of etchant, said etching head including one or more output orifices in fluid communication with said reservoir; means for receiving control signals; and means for controllably ejecting etchant out of the or each orifice in response to received control signals.

37. The etching head cartridge of claim 36 further including the technical features of any of claims 7 to 12.

38. An etching apparatus comprising means for mounting an etching head and means for generating control signals for controlling the operation of said etching head, said etching apparatus including vibration means for vibrating a piece of etchable material while etchant is being deposited thereon.

39. An etching apparatus for use in an etching system for forming an item having a desired shape or pattern from an initial piece of etchable material, said etching apparatus comprising means for carrying an etching head mounted in an etching head carriage at least back and fourth along a scanning path relative to said etchable material and means for generating control signals for controlling the movement of the etching head carriage and for generating control signals for controlling the ejection of etchant droplets from said etching head, wherein said carrying means includes a guide rail and a bearing member for slidably attaching the etching head carriage to the guide rail, and wherein said guide rail and said bearing member are formed from a metal-etchant resistant material.

40. The etching apparatus of claim 39 further including a distance sensor for measuring the distance from said distance sensor to a predetermined location or locations on a piece of etchable material to be etched.

41. The etching apparatus of claim 39 or 40 wherein the carrying means is additionally operable to move said etching head back and fourth in an elevation direction which is substantially perpendicular to said scanning path and substantially parallel to the direction of flight of etchant droplets ejected by said etching head.

42. The etching apparatus of claim 39, 40 or 41 including a reservoir of metal-etchant.

43. The etching apparatus of claim 42 further comprising one or more further reservoirs of different metal etchants.

44. A host device for controlling an etching apparatus forming part of an etching system for forming an item having a desired shape or pattern from an initial piece of etchable material, said host device including means for receiving design data representative of the desired shape or pattern, means for identifying the location of the or each portion of said initial piece of material to be removed by etchant and means for generating data representative of the portions of said initial piece of etchant material to be removed by etching and expressing said representative data in terms of a number of volume elements in which volume elements within said portions to be removed by etching are designated as elements to be removed.

45. The host device of claim 44 further operable to express said representative data in terms of layers of volume elements in which each layer is one volume element thick and to generate data representative of the number of complete passes by said etching head over said etchable material required to remove etchable material to the depth equivalent to depth of each volume element within a layer for a given maximum average deposition of etchant per unit surface area of the etchable material per pass.

46. A method of forming an item having a desired shape or pattern from an initial piece of etchable material, said method comprising the steps of receiving design data representative of the desired shape or pattern; processing said design data (i) to identify the location of the or each portion of said initial piece of etchable material to be removed by etching, and (ii) from the or each identified location, generating control signals for controlling the operation of an etching head having an output orifice in communication with a supply of etchant and means for controllably ejecting etchant out of the orifice onto the etchable material in response to the control signals; and applying said generated control signals to said ejecting means in order to selectively eject etchant from said orifice onto said initial piece of etchable material to form said item with the desired shape or pattern.

47. The method of claim 46 comprising controlling the temperature of the etchant.

48. The method of claim 47 comprising heating the etchant prior to being ejected to within a desired temperature range.

49. The method of any of claims 46 to 48 including supplying etchant from an etchant reservoir formed integrally with the etching head.

50. The method of any of claims 46 to 49 including controllably ejecting etchant from an orifice by applying pressure to the etchant to force it from the orifice.

51. The method of claim 50 wherein the step of applying pressure to the etchant includes controllably generating a vapour bubble by means of an electro-thermal transducer to increase the pressure applied to the etchant.

52. The method of claim 51 wherein the step of forming a vapour bubble comprises forming a vapour bubble in a working fluid in pressure communication with the etchant.

53. The method of claim 51 wherein the step of applying pressure to the etchant includes controllably changing the shape of a piezo-electric element to modify the pressure applied to the etchant.

54. The method of any preceding claim including the step of selectively charging droplets of etchant ejected from said orifice and controlling the charged droplets of etchant by the application of a variable electric field.

55. The-method of any of claims 46 to 54 including the step of introducing water at a controlled rate into an etchant stream flowing from said supply of etchant to said orifice, whereby the concentration of etchant ejected may be modified by modifying the rate at which water is introduced into the etchant stream.

56. The method of claim 55 including passing the etchant stream over a heating element approximately at the same time as, or after, introducing water to the etching steam.

57. The method of any of claims 46 to 56 including relatively moving the etching head and the etchable material.

58. The method of claim 57 including causing reciprocal relative movement between the etching head and the etching material along the scanning path.

59. The method of claim 58 further comprising causing reciprocal relative movement between the etching head and the etchable material along a sub-scanning path which is different from the scanning path, said scanning path and sub-scanning path lying approximately within a scanning plane.

60. The method of claim 59 wherein the sub-scanning path is substantially orthogonal to the scanning path.

61. The method of claim 59 or 60 further including moving either or both of the etching head and the etchable material towards or away from the scanning plane.

62. The method of claim 61 wherein the etching head and etchable material are moved relative to one another in an elevation path which is substantially orthogonal to the scanning plane.

63. The method of any of claims 56 to 61 wherein the etching head is moved whilst the etchable material is maintained stationary.

64. The method of any of claims 57 to 63 including measuring the distance between a distance sensor and the surface of said material to be etched and using the distance information to assist with moving the etching head and the etchable material relative to one another.

65. The method of any of claims 45 to 63 further including determining the shape or pattern of the etchable material and using this information to control the ejection of etchant droplets to assist in generating the desired shape or pattern.

66. The method of any of claims 46 to 65 including receiving billet data representative of the size and shape of the initial piece of etchable material and comparing the billet data with the design data in order to derive the item having the desired shape or pattern.

67. The method of any claims 46 to 66 including generating a negative shape or pattern from said design data which identifies the location of the or each portion to be removed.

68. The method of claim 67 including dividing said negative shape or pattern into a plurality of volume elements in which volume elements which fall substantially within a portion to be removed are designated as volume elements to be removed and the remaining volume elements are designated as volume elements to be kept.

69. The method of any of claims 46 to 68 including forming the desired shape or pattern by applying etchant to the etchable material in phases each of which removes etchable material to a predetermined depth.

70. The method of claim 69 when dependent upon claim 68 wherein each volume element has a depth which corresponds to the predetermined depth of etchable material which is removed in each phase.

71. The method of any of claims 46 to 70 further including identifying a boundary between a portion of said etchable material which is not to be removed by etching and a portion of said etchable material which is to be removed by etching, and controlling the etching system to deposit a different amount of etchant per volume of etchable material to be removed in the vicinity of said boundary compared to the amount of etchant per volume of etchable material to be removed deposited away from said boundary.

72. The method of any of claims 46 to 71 further including vibrating said etchable material such that the speed with which newly deposited etchant becomes into contact with unetchable material is increased.

73. The method of any of claim 46 to 72 wherein an etchant is deposited onto the surfaces of said etchable material at a rate which is greater than one tenth of a litre per square meter per minute.

74. A method of manufacturing an etchant cartridge for use in an etchant ejecting apparatus comprising the steps of:
providing a cartridge container;
filing the cartridge container with etchant; and
sealing the cartridge with an openable seal.

75. A method of manufacturing an etching head cartridge having an etching head and a reservoir of etchant, said method comprising the steps of:
providing a cartridge container having an etching head and a reservoir for storing etchant formed therein;
filing the reservoir with etchant; and
sealing the cartridge.

76. A method of ejecting etchant from an etching head comprising the steps of receiving one or more control signals and ejecting droplets of etchant in response to the control signals.

77. A method of operating an etching apparatus comprising the steps of receiving etching data; and
generating control signals from said etching data for driving an etching head to selectively deposit droplets of etchant onto a piece of etchable material in accordance with the etching data.

78. A method of claim 77 further including controlling a vibration means to vibrate and thus cause the piece of etchable material to vibrate.

79. The method of either one of claims 78 or 79 including detecting the distance from a distance sensor mounted on the etching apparatus to a predetermined location or locations on the piece of etchable material to be etched and using this information to control the movement of the etching head.

80. A method of any one of claims 77, 78 and 79 including controlling the movement of the etching head back and fourth in an elevation direction which is substantially perpendicular to said scanning path and substantially parallel to the direction of flight of etchant droplets ejected by said ejecting head.

81. A method of controlling an etching apparatus forming part of an etching system for forming an item of a desired shape or pattern from an initial piece of etchable material, said method including receiving design data representative of the desired shape or pattern, identifying the location of the or each portion of said initial piece of material to be removed by etchant and generating data representative of the portions of said initial piece of etchant material to be removed by etching and expressing said representative data in terms of a number of volume elements in which volume elements within said portion to be removed by etching are designated as elements to be removed.

82. The method of claim 81 further including expressing said representative data in terms of layers of volume elements in which each layer is one volume element thick and generating data representative of the number of complete passes by said etching head over said etchable material required to remove etchable material to a depth equivalent to depth of each volume element in a layer for a given average rate of deposition of etchant per unit surface area of the etchable material per pass.

83. A method of forming a wanted item from an initial piece of etchable material, said method comprising the step of:
selectively depositing etchant onto unwanted portions of the initial piece of etchable material, whereby said unwanted portions are removed to generate said wanted item.

84. The method of claim 83, further comprising periodically cleaning said initial piece of etchable material during deposition of etchant or in between successive depositions of etchant.

85. The method of claim 83 or 84, wherein the step of selectively depositing etchant includes selectively ejecting one or more droplets of etchant onto said etchable material from one or more nozzles formed within an etching head.

86. The method of claim 3, wherein each droplet has a volume of between 500 and 5000 picolitres.

87. The method of claim 85 or 86, further comprising moving the etching head relative to the etchable material and timing the ejection of droplets of etchant from said one or more nozzles such that droplets of etchant are selectively deposited only on said unwanted portions.

88. The method of claim 87, wherein said etching head and said etchable material are additionally moved relative to one another in a direction towards or away from one another to maintain the etching head substantially as close as possible to the surface of the etchable material onto which droplets of etchant are selectively ejected.

89. The method of any of claims 83 to 88, wherein the etchant is drawn from an etchant reservoir to the point of its ejection substantially without contacting any material which is etachable by said etchant.

90. A method of forming a wanted item from an initial piece of etching material, said method comprising the steps of:
generating data representative of the portions of said initial price of material to be removed in order to generate said wanted item;
expressing said data in terms of a number of layers of volume elements in which elements within said portions to be removed are designated as elements to be removed; and
controlling an etching apparatus to eject droplets of etchant onto said initial piece of material according to the data expressing which volume elements are to be removed on a layer by layer basis.

91. The method of claim 90, further including cleaning the initial piece of material to remove products of etching after one or more droplets have been deposited on a particular location on said initial piece of material, and prior to ejecting one or more further droplets onto said location.

92. A method of manufacturing a product comprising the steps of:
forming one or more mould tools using the method of any one of claims 45 to 73 or 83 to 91;
installing the mould tools into moulded material forming apparatus; and
operating the moulded material forming apparatus to form one or more components or products.

93. The method of claim 92, further comprising assembling said one or more components or products with one or more further components to form an assembled product.

94. A method of forming a printed item comprising the steps of:
forming one or more printing plates using the method of any one of claims 1 to 11;
installing the printing plates into a printing apparatus; and
operating the printing apparatus to form one or more printed items.

95. Processor implementable instructions carried on a carrier medium for causing a processor to carry out the method of any one of claims 46 to 94.

96. Etching system implementable instructions carried on a carrier medium for causing an etching system to carry out the method of any one of claims 46 to 94.

97. An etching system for forming an item having a desired shape or pattern from an initial piece of etchable material, said system comprising:
a supply of etchant;
an etching head having an output hole in communication with said etchant supply and means for controllably ejecting etchant out of the hole onto the etchable material in response to a control signal;
means for receiving design data representative of the desired shape or pattern for the item;
means for processing said design data:
(i) to identify the location of the or each portion of said initial piece of etchable material to be removed by etching; and
(ii) from the or each identified location, to generate control signals for controlling the operation of the ejecting means; and
means for applying said generated control signals to said ejecting means in order to selectively eject etchant from said hole onto said initial piece of etchable material to form said item with the desired shape or pattern.
